(19) United States
(12) Patent Application Publication
(10) Pub. No.: US 2026/0271354 A1
(43) Pub. Date: Sep. 10, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kazusa ARIMA, Nomi Ishikawa (JP); Daiki YOSHIKAWA, Nonoichi Ishikawa (JP)

(21) Appl. No.: 19/229,925

(22) Filed: Jun. 5, 2025

(30) Foreign Application Priority Data
Mar. 7, 2025 (JP) 2025-036637

(51) Int. Cl. H10D 62/10; H10D 12/00; H10D 84/00

(52) U.S. Cl. CPC H10D 62/126; H10D 12/481; H10D 84/161

(57) ABSTRACT

A semiconductor part includes a first semiconductor layer, a second semiconductor layer positioned between the first electrode and the first semiconductor layer, a third semiconductor layer positioned between the first electrode and the second semiconductor layer, a fourth semiconductor layer positioned between the first semiconductor layer and the second electrode, a fifth semiconductor layer positioned between the fourth semiconductor layer and the second electrode, a sixth semiconductor layer positioned between the first electrode and the second semiconductor layer, a seventh semiconductor layer positioned between the first semiconductor layer and the second electrode, and an eighth semiconductor layer positioned inside the second semiconductor layer. A portion of the second semiconductor layer is positioned between the eighth semiconductor layer and the first semiconductor layer. An interface between the first semiconductor layer and the second semiconductor layer does not include a step above the eighth semiconductor layer.

### CROSS-REFERENCE TO RELATED APPLICATION

This application is based upon and claims the benefit of priority from Japanese Patent Application No.2025-036637, filed on Mar. 7, 2025; the entire contents of which are incorporated herein by reference.

### FIELD

Embodiments described herein relate generally to a semiconductor device.

### BACKGROUND

IGBTs (Insulated Gate Bipolar Transistors) are widely used as semiconductor devices for power control. In many applications using IGBTs, there is a mode in which a return current flows from the emitter side to the collector side; and a FWD (Free-Wheel Diode) is connected in parallel to the IGBT to carry the return current. A reverse-conducting IGBT (RC-IGBT) is a semiconductor device in which the FWD and the IGBT are formed in one chip.

### BRIEF DESCRIPTION OF THE DRAWINGS

FIG. 1 is a schematic cross-sectional view of a semiconductor device of a first embodiment;

FIG. 2 is a schematic plan view of a semiconductor part of the semiconductor device of the first embodiment;

FIG. 3 is a schematic cross-sectional view of a semiconductor device of a second embodiment;

FIG. 4 is a schematic cross-sectional view of a semiconductor device of a third embodiment;

FIG. 5 is a schematic cross-sectional view of a semiconductor device of a fourth embodiment;

FIG. 6 is a schematic cross-sectional view of a semiconductor device of a fifth embodiment; and

FIG. 7A to FIG. 8B are schematic cross-sectional views showing a method for manufacturing the semiconductor device of the embodiment.

### DETAILED DESCRIPTION

According to one embodiment, a semiconductor device includes a first electrode; a second electrode; a semiconductor part positioned between the first electrode and the second electrode in a first direction, the semiconductor part including a transistor region and a diode region, the diode region being adjacent to the transistor region in a direction crossing the first direction; and a third electrode positioned in the semiconductor part in at least the transistor region, the semiconductor part including a first semiconductor layer positioned in the transistor region and the diode region, the first semiconductor layer being of a first conductivity type, a second semiconductor layer positioned between the first electrode and the first semiconductor layer in the transistor region and the diode region, the second semiconductor layer being of the first conductivity type and having a higher first-conductivity-type impurity concentration than the first semiconductor layer, a third semiconductor layer positioned between the first electrode and the second semiconductor layer in the transistor region, the third semiconductor layer being of a second conductivity type and being electrically connected with the first electrode, a fourth semiconductor layer positioned between the first semiconductor layer and the second electrode in the transistor region, the fourth semiconductor layer being of the second conductivity type, a fifth semiconductor layer positioned between the fourth semiconductor layer and the second electrode in the transistor region, the fifth semiconductor layer being of the first conductivity type and being electrically connected with the second electrode, a sixth semiconductor layer positioned between the first electrode and the second semiconductor layer in the diode region, the sixth semiconductor layer being adjacent to the third semiconductor layer in the direction crossing the first direction, the sixth semiconductor layer being electrically connected with the first electrode, the sixth semiconductor layer being of the first conductivity type and having a higher first-conductivity-type impurity concentration than the first semiconductor layer, a seventh semiconductor layer positioned between the first semiconductor layer and the second electrode in the diode region, the seventh semiconductor layer being of the second conductivity type and being electrically connected with the second electrode, and an eighth semiconductor layer positioned inside the second semiconductor layer, the eighth semiconductor layer being positioned at a boundary between the transistor region and the diode region, the eighth semiconductor layer being of the second conductivity type, a portion of the second semiconductor layer being positioned between the eighth semiconductor layer and the first semiconductor layer, an interface between the first semiconductor layer and the second semiconductor layer not including a step above the eighth semiconductor layer.

According to one embodiment, a semiconductor device includes a first electrode; a second electrode; a semiconductor part positioned between the first electrode and the second electrode in a first direction, the semiconductor part including a transistor region and a diode region, the diode region being adjacent to the transistor region in a direction crossing the first direction; and a third electrode positioned in the semiconductor part in at least the transistor region, the semiconductor part including a first semiconductor layer positioned in the transistor region and the diode region, the first semiconductor layer being of a first conductivity type, a second semiconductor layer positioned between the first electrode and the first semiconductor layer in the transistor region and the diode region, the second semiconductor layer being of the first conductivity type and having a higher first-conductivity-type impurity concentration than the first semiconductor layer, a third semiconductor layer positioned between the first electrode and the second semiconductor layer in the transistor region, the third semiconductor layer being of a second conductivity type and being electrically connected with the first electrode, a fourth semiconductor layer positioned between the first semiconductor layer and the second electrode in the transistor region, the fourth semiconductor layer being of the second conductivity type, a fifth semiconductor layer positioned between the fourth semiconductor layer and the second electrode in the transistor region, the fifth semiconductor layer being of the first conductivity type and being electrically connected with the second electrode, a sixth semiconductor layer positioned between the first electrode and the second semiconductor layer in the diode region, the sixth semiconductor layer being adjacent to the third semiconductor layer in the direction crossing the first direction, the sixth semiconductor layer being electrically connected with the first electrode, the sixth semiconductor layer being of the first conductivity type and having a higher first-conductivity-type impurity concentration than the first semiconductor layer, a seventh semiconductor layer positioned between the first semiconductor layer and the second electrode in the diode region, the seventh semiconductor layer being of the second conductivity type and being electrically connected with the second electrode, and an eighth semiconductor layer positioned inside the second semiconductor layer, the eighth semiconductor layer being positioned between a boundary between the transistor region and the diode region and a boundary between the third semiconductor layer and the sixth semiconductor layer in the direction crossing the first direction, the eighth semiconductor layer being of the second conductivity type, a portion of the second semiconductor layer being positioned between the eighth semiconductor layer and the first semiconductor layer, an interface between the first semiconductor layer and the second semiconductor layer not including a step above the eighth semiconductor layer.

Exemplary embodiments will now be described with reference to the drawings. Similar components in the drawings are marked with like reference numerals. In the drawings, a direction along a Z-axis is referred to as a first direction Z; a direction along an X-axis is referred to as a second direction X; and a direction along a Y-axis is referred to as a third direction Y. The second direction X and the third direction Y are directions that cross the first direction Z. According to the embodiment, for example, the first direction Z, the second direction X, and the third direction Y are orthogonal to each other. In the description of the specification, for example, the arrow direction of the Z-axis may be referred to as relatively up or above; and the opposite direction of the arrow of the Z-axis may be referred to as relatively down or below.

In the specification, the thickness of each component represents the maximum value of the thickness in the first direction Z. In the specification, the distance in a specific direction between components represents the shortest distance in the specific direction.

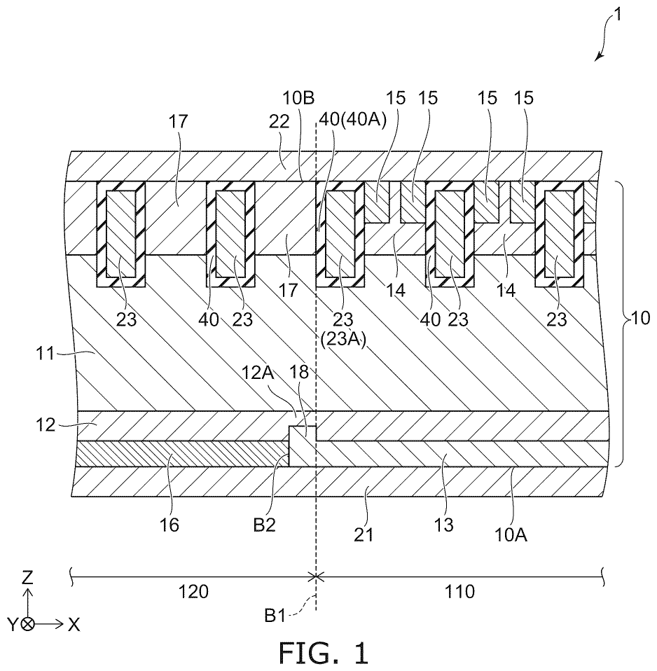

As shown in FIG. 1, the semiconductor device 1 includes a first electrode 21, a second electrode 22, a third electrode 23, a semiconductor part 10, and an insulating film 40.

The semiconductor part 10 is positioned between the first electrode 21 and the second electrode 22 in the first direction Z. The semiconductor part 10 includes a first surface 10A, and a second surface 10B positioned at the side opposite to the first surface 10A in the first direction Z. The first electrode 21 is located at the first surface 10A. The second electrode 22 is located at the second surface 10B.

For example, silicon can be used as the material of the semiconductor part 10. Or, for example, silicon carbide, gallium nitride, etc., may be used as the material of the semiconductor part 10. Although a first conductivity type is described as an n-type and a second conductivity type is described as a p-type in the semiconductor part 10 according to the embodiment, the first conductivity type may be the p-type; and the second conductivity type may be the n-type.

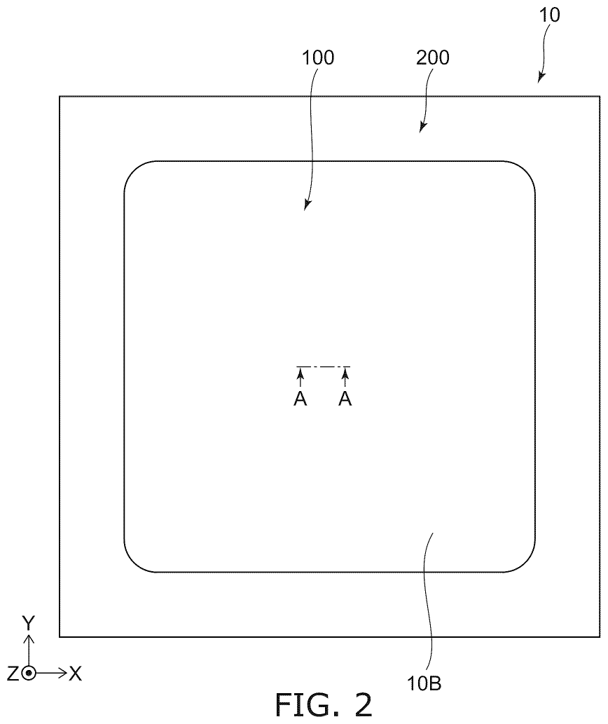

FIG. 2 is a schematic plan view of the second surface 10B of the semiconductor part 10. The cross section of the semiconductor part 10 shown in FIG. 1 corresponds to an A-A cross section of FIG. 2.

The semiconductor part 10 includes an element region 100 and a termination region 200. The termination region 200 is positioned between the element region 100 and the outer edge of the semiconductor part 10 in the second and third directions X and Y. The termination region 200 surrounds the element region 100 when viewed in plan.

As shown in FIG. 1, the semiconductor part 10 includes a transistor region 110 and a diode region 120. According to the embodiment, the diode region 120 is adjacent to the transistor region 110 in the second direction X. The transistor region 110 and the diode region 120 are included in the element region 100. For example, the transistor region 110 and the diode region 120 are alternately arranged in the second direction X in the element region 100.

The semiconductor part 10 includes an n-type first semiconductor layer 11, an n-type second semiconductor layer 12, a p-type third semiconductor layer 13, a p-type fourth semiconductor layer 14, an n-type fifth semiconductor layer 15, an n-type sixth semiconductor layer 16, a p-type seventh semiconductor layer 17, and a p-type eighth semiconductor layer 18.

The transistor region 110 includes an IGBT. In the IGBT of the transistor region 110, the first electrode 21 functions as a collector electrode; the second electrode 22 functions as an emitter electrode; the first semiconductor layer 11 functions as an n-type base layer (or a drift layer); the second semiconductor layer 12 functions as an n-type buffer layer; the third semiconductor layer 13 functions as a p-type collector layer; the fourth semiconductor layer 14 functions as a p-type base layer; and the fifth semiconductor layer 15 functions as an n-type emitter layer.

The first semiconductor layer 11 (the n-type base layer) is continuous in the transistor region 110 and the diode region 120.

The second semiconductor layer 12 (the n-type buffer layer) is positioned between the first electrode 21 and the first semiconductor layer 11 in the transistor region 110 and the diode region 120. The second semiconductor layer 12 is continuous in the transistor region 110 and the diode region 120. The n-type impurity concentration of the second semiconductor layer 12 is greater than the n-type impurity concentration of the first semiconductor layer 11.

The third semiconductor layer 13 (the p-type collector layer) is positioned between the first electrode 21 and the second semiconductor layer 12 in the transistor region 110. The third semiconductor layer 13 contacts the first electrode 21 and is electrically connected with the first electrode 21.

The fourth semiconductor layer 14 (the p-type base layer) is positioned between the first semiconductor layer 11 and the second electrode 22 in the transistor region 110. A portion of the fourth semiconductor layer 14 contacts the second electrode 22. The fourth semiconductor layer 14 contacts the first semiconductor layer 11 in the first direction Z and forms a p-n junction with the first semiconductor layer 11.

The fifth semiconductor layer 15 (the n-type emitter layer) is positioned between the fourth semiconductor layer 14 and the second electrode 22 in the transistor region 110. The n-type impurity concentration of the fifth semiconductor layer 15 is greater than the n-type impurity concentration of the first semiconductor layer 11. The fifth semiconductor layer 15 is electrically connected with the second electrode 22. For example, the second electrode 22 contacts the upper surface of the fifth semiconductor layer 15. The second electrode 22 may have a trench contact structure that contacts the side surface of the fifth semiconductor layer 15.

The diode region 120 includes a diode connected in parallel to the IGBT of the transistor region 110. In the diode of the diode region 120, the first electrode 21 functions as a cathode electrode; the second electrode 22 functions as an anode electrode; the sixth semiconductor layer 16 functions as an n-type cathode layer; and the seventh semiconductor layer 17 functions as a p-type anode layer.

The sixth semiconductor layer 16 (the n-type cathode layer) is positioned between the first electrode 21 and the second semiconductor layer 12 in the diode region 120. The n-type impurity concentration of the sixth semiconductor layer 16 is greater than the n-type impurity concentration of the first semiconductor layer 11. The sixth semiconductor layer 16 contacts the first electrode 21 and is electrically connected with the first electrode 21. For example, the sixth semiconductor layer 16 (the n-type cathode layer) is adjacent to the third semiconductor layer 13 (the p-type collector layer) in the second direction X.

The seventh semiconductor layer 17 (the p-type anode layer) is positioned between the first semiconductor layer 11 and the second electrode 22 in the diode region 120 and is electrically connected with the second electrode 22. The seventh semiconductor layer 17 contacts the first semiconductor layer 11 in the first direction Z and forms a p-n junction with the first semiconductor layer 11.

The fifth semiconductor layer 15 (the n-type emitter layer) is not located in the diode region 120.

The third electrode 23 extends downward from the second surface 10B side of the semiconductor part 10 in at least the transistor region 110, and is positioned inside the semiconductor part 10. In the transistor region 110, the lower end of the third electrode 23 is positioned lower than the p-n junction between the fourth semiconductor layer 14 (the p-type base layer) and the first semiconductor layer 11 (the n-type base layer). For example, conductive polycrystalline silicon can be used as the material of the third electrode 23.

The insulating film 40 is located between the third electrode 23 and the semiconductor part 10. In the transistor region 110, the side surface of the third electrode 23 faces the fourth semiconductor layer 14 (the p-type base layer) via the insulating film 40. The insulating film 40 also is located between the third electrode 23 and the second electrode 22.

According to the embodiment, the third electrode 23 also is located in the diode region 120. The third electrode 23 extends downward from the second surface 10B side of the semiconductor part 10 in the diode region 120, and is positioned inside the semiconductor part 10. In the diode region 120, the lower end of the third electrode 23 is positioned lower than the p-n junction between the seventh semiconductor layer 17 (the p-type anode layer) and the first semiconductor layer 11 (the n-type base layer). The third electrode 23 may not be located in the diode region 120.

According to the embodiment, multiple third electrodes 23 are separated from each other in the second direction X and are arranged in the transistor region 110 and the diode region 120. Each third electrode 23 extends in the third direction Y.

The multiple third electrodes 23 that are located in the transistor region 110 include a third electrode 23A positioned furthest toward the diode region 120 side. An insulating film 40A that covers the side surface of the third electrode 23A among the two side surfaces in the second direction X positioned at the diode region 120 side is adjacent to the seventh semiconductor layer 17 (the p-type anode layer). According to the embodiment, the boundary between the insulating film 40A and the seventh semiconductor layer 17 (the p-type anode layer) is taken to be a boundary B1 between the transistor region 110 and the diode region 120. A virtual line that extends in the first direction Z through the boundary B1 is illustrated by a dashed line in the cross-section of FIG. 1 which shows the boundary B1.

A boundary B2 between the third semiconductor layer 13 (the p-type collector layer) and the sixth semiconductor layer 16 (the n-type cathode layer) may or may not match the boundary B1 between the transistor region 110 and the diode region 120. The boundary B2 between the third semiconductor layer 13 (the p-type collector layer) and the sixth semiconductor layer 16 (the n-type cathode layer) may be positioned at the transistor region 110 side or at the diode region 120 side with respect to the boundary B1 between the transistor region 110 and the diode region 120. In the example shown in FIG. 1, the boundary B2 between the third semiconductor layer 13 and the sixth semiconductor layer 16 is positioned at the diode region 120 side.

The third electrode 23 that is located in the transistor region 110 functions as a gate electrode (a trench gate) of the IGBT, and is connected with a gate wiring part (not illustrated). For example, the end part of the third electrode 23 (the gate electrode) extending in the third direction Y from the transistor region 110 to the termination region 200 is connected with a gate wiring part in the termination region 200. The third electrode 23 (the gate electrode) may be connected with the gate wiring part in the element region 100.

The third electrode 23 that is located in the diode region 120 is not connected to a gate wiring part, and is connected with, for example, the second electrode 22. For example, the end part of the third electrode 23 extending in the third direction Y from the diode region 120 to the termination region 200 is connected with the second electrode 22 in the termination region 200. The third electrode 23 may be connected with the second electrode 22 in the element region 100. The third electrode 23 that is located in the diode region 120 does not function as a gate electrode of a transistor. By forming dummy trench electrodes in the diode region 120, fluctuation of the shapes and/or dimensions of the trenches and the third electrodes 23 (the gate electrodes) formed in the transistor region 110 can be reduced, and fluctuation of the breakdown voltage in the transistor region 110 and the diode region 120 can be reduced.

In the IGBT operation of the transistor region 110, a positive potential is applied to the first electrode 21 (the collector electrode); and a ground potential is applied to the second electrode 22 (the emitter electrode). When a potential that is greater than a prescribed threshold (a potential that is higher than the potential of the second electrode 22 (the emitter potential)) is applied to the third electrode 23 (the gate electrode) of the transistor region 110, an inversion layer (an n-type channel) is formed in the region of the fourth semiconductor layer 14 (the p-type base layer) facing the third electrode 23; and electrons are injected from the second electrode 22 into the first semiconductor layer 11 (the n-type base layer) via the fifth semiconductor layer 15 (the n-type emitter layer) and the n-type channel. Therefore, the third semiconductor layer 13 (the p-type collector layer) is biased to be positive with respect to the first semiconductor layer 11; holes are injected from the third semiconductor layer 13 into the first semiconductor layer 11; and the IGBT of the transistor region 110 is switched to an on-state.

When a potential that is less than the threshold is applied to the third electrode 23 (the gate electrode) of the transistor region 110, the n-type channel disappears, and the IGBT is switched to an off-state. In the off-state of the IGBT, a depletion layer extends through the first semiconductor layer 11 from the p-n junction between the fourth semiconductor layer 14 and the first semiconductor layer 11 and the boundary between the insulating film 40 and the first semiconductor layer 11; and the breakdown voltage is maintained. The second semiconductor layer 12 (the n-type buffer layer) that has a higher n-type impurity concentration than the first semiconductor layer 11 (the n-type base layer) suppresses punch-through in which the depletion layer reaches the third semiconductor layer 13 (the p-type collector layer).

In the diode operation of the diode region 120, when a forward voltage such that the potential (the anode potential) of the second electrode 22 becomes higher than the potential (the cathode potential) of the first electrode 21 is applied between the second electrode 22 and the first electrode 21, holes are injected from the seventh semiconductor layer 17 (the p-type anode layer) into the first semiconductor layer 11; electrons are injected from the sixth semiconductor layer 16 (the n-type cathode layer) into the first semiconductor layer 11; and a forward current flows in the diode of the diode region 120.

In the IGBT mode of the semiconductor device 1, the IGBT is switched on, and the diode is switched off. In the diode mode of the semiconductor device 1, the IGBT is switched off, and the diode is switched on. The IGBT mode and the diode mode are alternately repeated.

In the IGBT mode, the potential barrier between the second semiconductor layer 12 (the n-type buffer layer) and the third semiconductor layer 13 (the p-type collector layer) may cause a portion of the electron current supplied from the fifth semiconductor layer 15 (the n-type emitter layer) to flow across the second semiconductor layer 12 (the n-type buffer layer) and flow into the sixth semiconductor layer 16 (the n-type cathode layer) in the diode region 120. This operation is called a MOS operation. The MOS operation causes snapback in which the I-V characteristic (represented by a graph in which the horizontal axis is the voltage and the vertical axis is the current) switches to a negative resistance region, which makes the desired control of the IGBT operation difficult.

According to the embodiment, snapback can be suppressed by the p-type eighth semiconductor layer 18 that is positioned inside the second semiconductor layer 12 (the n-type buffer layer) on the third semiconductor layer 13 (the p-type collector layer) and is positioned at the boundary B1 between the transistor region 110 and the diode region 120. The eighth semiconductor layer 18 being positioned at the boundary B1 between the transistor region 110 and the diode region 120 means that the eighth semiconductor layer 18 is positioned so that the eighth semiconductor layer 18 contacts the virtual line (the dashed line) passing through the boundary B1 when viewed in cross-section as described above. According to the embodiment, the side surface of the eighth semiconductor layer 18 at the transistor region 110 side contacts the virtual line passing through the boundary B1.

In the first direction Z, the eighth semiconductor layer 18 is positioned on the third semiconductor layer 13 (the p-type collector layer), but is not positioned on the sixth semiconductor layer 16 (the n-type cathode layer). According to the embodiment, the eighth semiconductor layer 18 contacts the third semiconductor layer 13. The eighth semiconductor layer 18 does not extend through the second semiconductor layer 12 in the first direction Z. In the first direction Z, a portion 12A of the second semiconductor layer 12 is positioned between the eighth semiconductor layer 18 and the first semiconductor layer 11.

The thickness in the first direction Z of the second semiconductor layer 12 is reduced at the portion 12A adjacent to the boundary B1 between the transistor region 110 and the diode region 120. The thickness in the first direction Z of the portion 12A of the second semiconductor layer 12 positioned on the eighth semiconductor layer 18 is less than the thickness in the first direction Z of the second semiconductor layer 12 at the portion positioned on the third semiconductor layer 13 in the transistor region 110 and the thickness in the first direction Z of the second semiconductor layer 12 at the portion positioned on the sixth semiconductor layer 16 in the diode region 120. As a result, the electron current that flows across the second semiconductor layer 12 (the n-type buffer layer) in the IGBT mode does not easily flow into the sixth semiconductor layer 16 side of the diode region 120; and snapback can be suppressed. The eighth semiconductor layer 18 functions as a resistance when the electron current flowing across the second semiconductor layer 12 flows toward the diode region 120 side. When the ratio of the thickness of the eighth semiconductor layer 18 to the thickness of the second semiconductor layer 12 is ½, the resistance approximately doubles.

For example, when the semiconductor device 1 is designed for a breakdown voltage of 1,200 V, the n-type impurity concentration of the second semiconductor layer 12 (the n-type buffer layer) can be set to 1×10¹⁶ cm⁻³. To suppress punch-through in such a case, it is favorable to set the thickness of the portion 12A of the second semiconductor layer 12 on the eighth semiconductor layer 18 to be not less than 0.2 μm.

If the eighth semiconductor layer 18 is positioned at the transistor region 110 side with respect to the boundary B1 between the transistor region 110 and the diode region 120, the eighth semiconductor layer 18 does not easily function as a resistance to the electron current flowing downward from directly above the eighth semiconductor layer 18 in the transistor region 110. It is therefore favorable for the eighth semiconductor layer 18 to be positioned at the diode region 120 side in the second direction X with respect to the boundary B1 between the transistor region 110 and the diode region 120.

The interface between the first semiconductor layer 11 and the second semiconductor layer 12 does not include a step above the eighth semiconductor layer 18. The interface between the first semiconductor layer 11 and the second semiconductor layer 12 is not curved to be convex on the eighth semiconductor layer 18. The portion 12A of the second semiconductor layer 12 positioned on the eighth semiconductor layer 18 is not convex toward the first semiconductor layer 11 side. The first electrode 21 at the position below the eighth semiconductor layer 18 is not convex toward the semiconductor part 10 side. The interface between the first electrode 21 and the semiconductor part 10 at the position below the eighth semiconductor layer 18 is flat and is parallel to the second and third directions X and Y. The thickness in the first direction Z (the distance in the first direction Z between the first electrode 21 and the second electrode 22) of the portion of the semiconductor part 10 in which the eighth semiconductor layer 18 is positioned is equal to the thickness in the first direction Z (the distance in the first direction Z between the first electrode 21 and the second electrode 22) of a portion of the semiconductor part 10 in which the eighth semiconductor layer 18 is not positioned. In other words, the thickness in the first direction Z of the first semiconductor layer 11 is not partially thin above the eighth semiconductor layer 18. The distance in the first direction Z between the eighth semiconductor layer 18 and the seventh semiconductor layer 17 is less than the distance in the first direction Z between the sixth semiconductor layer 16 and the seventh semiconductor layer 17 and less than the distance in the first direction Z between the third semiconductor layer 13 and the fourth semiconductor layer 14. According to such a semiconductor device 1 according to the embodiment, a reduction of the breakdown voltage at the vicinity of the boundary B1 between the transistor region 110 and the diode region 120 can be suppressed.

Other embodiments will now be described; and mainly configurations different from those of the first embodiment above are described.

### SECOND EMBODIMENT

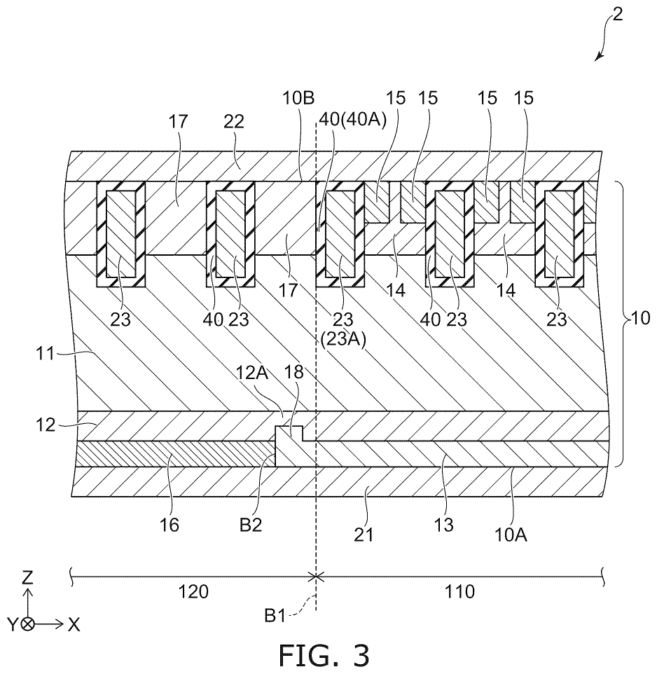

FIG. 3 is a schematic cross-sectional view of a semiconductor device 2 according to a second embodiment.

The eighth semiconductor layer 18 may not be at a position such that the eighth semiconductor layer 18 contacts the line passing through the boundary B1 between the transistor region 110 and the diode region 120. In the semiconductor device 2 according to the second embodiment, the eighth semiconductor layer 18 is positioned inside the second semiconductor layer 12 on the third semiconductor layer 13 and is positioned between the boundary B1 between the transistor region 110 and the diode region 120 and the boundary B2 between the third semiconductor layer 13 and the sixth semiconductor layer 16 in the second direction X. In such a case as well, the eighth semiconductor layer 18 can function as a resistance when the electron current flows across the second semiconductor layer 12 toward the diode region 120 side, and can suppress snapback.

### THIRD EMBODIMENT

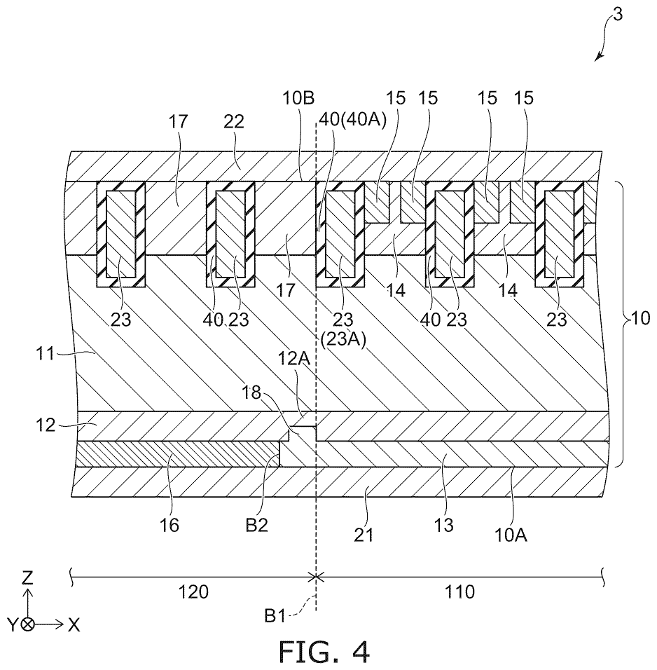

FIG. 4 is a schematic cross-sectional view of a semiconductor device 3 according to a third embodiment.

In the semiconductor device 3 according to the third embodiment, the boundary B2 between the third semiconductor layer 13 and the sixth semiconductor layer 16 is positioned further toward the diode region 120 side than the eighth semiconductor layer 18 in the second direction X. In such a case as well, the eighth semiconductor layer 18 can function as a resistance when the electron current flows across the second semiconductor layer 12 toward the diode region 120 side, and can suppress snapback.

### FOURTH EMBODIMENT

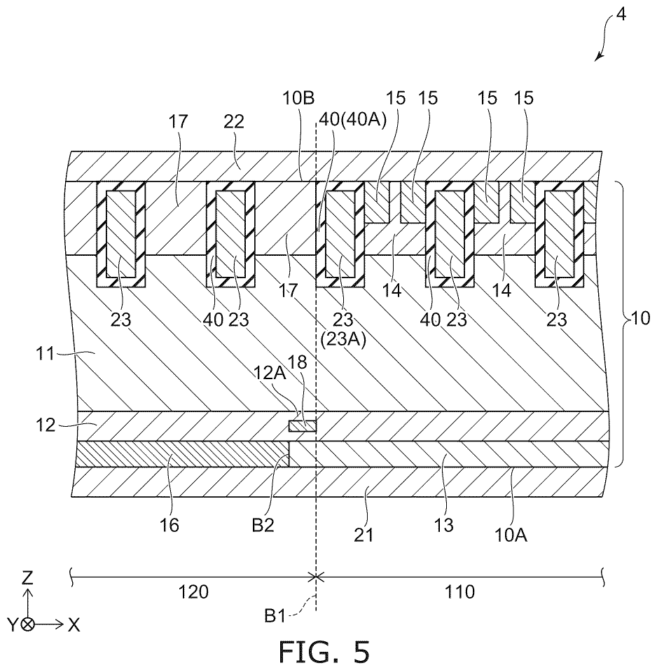

FIG. 5 is a schematic cross-sectional view of a semiconductor device 4 according to a fourth embodiment.

In the semiconductor device 4 according to the fourth embodiment, the eighth semiconductor layer 18 is separated from the third semiconductor layer 13 in the first direction Z. In such a case as well, the eighth semiconductor layer 18 can function as a resistance when the electron current flows across the second semiconductor layer 12 toward the diode region 120 side, and can suppress snapback.

Also, punch-through can be suppressed because the portion 12A of the second semiconductor layer 12 is positioned between the eighth semiconductor layer 18 and the first semiconductor layer 11 in the first direction Z.

### FIFTH EMBODIMENT

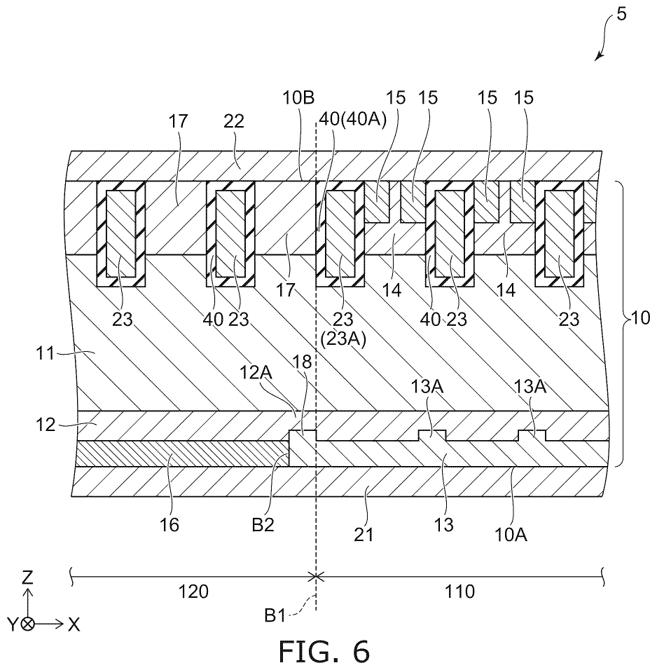

As in a semiconductor device 5 according to a fifth embodiment shown in FIG. 6, a part 13A of the third semiconductor layer 13 that is separated from the boundary B1 between the transistor region 110 and the diode region 120 may protrude to be convex toward the second semiconductor layer 12 side in the transistor region 110. That is, the convex part 13A of the third semiconductor layer 13 is not limited to the boundary B1 and may be periodically arranged.

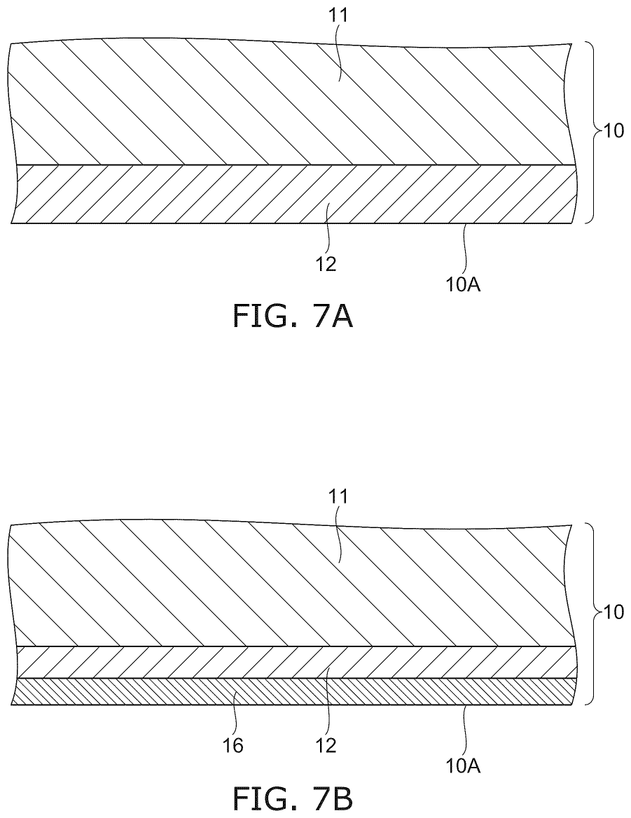

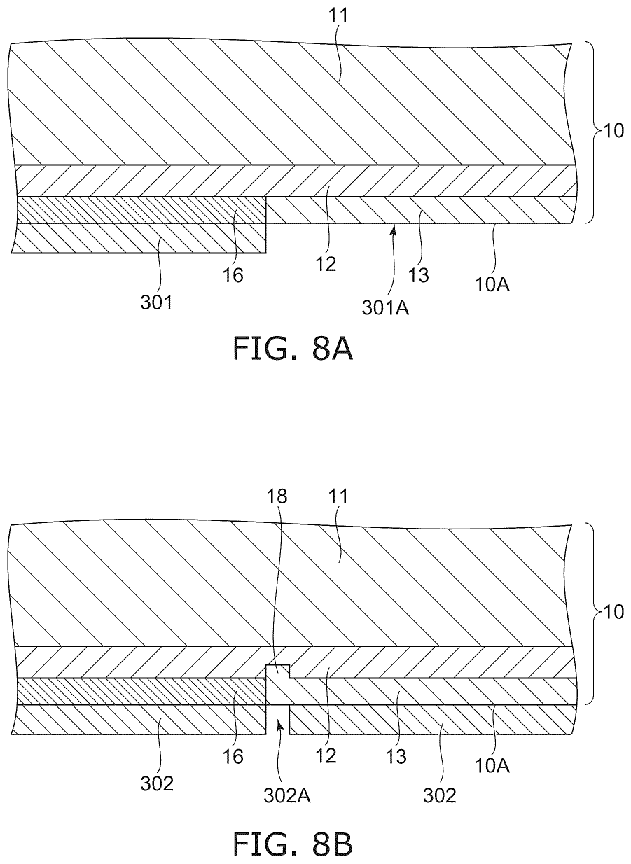

FIGS. 7A to 8B show an example of a method for manufacturing a semiconductor device according to an embodiment.

As shown in FIG. 7A, the second semiconductor layer 12 is formed in the entire surface of the first surface 10A by ion-implanting an impurity such as, for example, phosphorus (P), etc., into the first semiconductor layer 11 through the first surface 10A side.

After forming the second semiconductor layer 12, the sixth semiconductor layer 16 is formed in the entire surface of the first surface 10A as shown in FIG. 7B by ion-implanting an impurity such as, for example, phosphorus (P), etc., into the second semiconductor layer 12 through the first surface 10A side.

After forming the sixth semiconductor layer 16, a portion of the sixth semiconductor layer 16 at the first surface 10A side is covered with a resist 301 as shown in FIG. 8A. Then, the third semiconductor layer 13 is formed to be adjacent to the sixth semiconductor layer 16 by ion-implanting an impurity such as, for example, boron (B), etc., through the first surface 10A exposed in an opening 301A of the resist 301.

After forming the third semiconductor layer 13, the sixth semiconductor layer 16 and the third semiconductor layer 13 at the first surface 10A side are covered with a resist 302. A portion of the third semiconductor layer 13 is exposed in an opening 302A of the resist 302. Then, the eighth semiconductor layer 18 is formed by ion-implanting an impurity such as, for example, boron (B), etc., into a portion of the second semiconductor layer 12 through the first surface 10A via the opening 302A.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first electrode;
a second electrode;
a semiconductor part positioned between the first electrode and the second electrode in a first direction, the semiconductor part including a transistor region and a diode region, the diode region being adjacent to the transistor region in a direction crossing the first direction; and
a third electrode positioned in the semiconductor part in at least the transistor region,
the semiconductor part including
a first semiconductor layer positioned in the transistor region and the diode region, the first semiconductor layer being of a first conductivity type,
a second semiconductor layer positioned between the first electrode and the first semiconductor layer in the transistor region and the diode region, the second semiconductor layer being of the first conductivity type and having a higher first-conductivity-type impurity concentration than the first semiconductor layer,
a third semiconductor layer positioned between the first electrode and the second semiconductor layer in the transistor region, the third semiconductor layer being of a second conductivity type and being electrically connected with the first electrode,
a fourth semiconductor layer positioned between the first semiconductor layer and the second electrode in the transistor region, the fourth semiconductor layer being of the second conductivity type,
a fifth semiconductor layer positioned between the fourth semiconductor layer and the second electrode in the transistor region, the fifth semiconductor layer being of the first conductivity type and being electrically connected with the second electrode,
a sixth semiconductor layer positioned between the first electrode and the second semiconductor layer in the diode region, the sixth semiconductor layer being adjacent to the third semiconductor layer in the direction crossing the first direction, the sixth semiconductor layer being electrically connected with the first electrode, the sixth semiconductor layer being of the first conductivity type and having a higher first-conductivity-type impurity concentration than the first semiconductor layer,
a seventh semiconductor layer positioned between the first semiconductor layer and the second electrode in the diode region, the seventh semiconductor layer being of the second conductivity type and being electrically connected with the second electrode, and
an eighth semiconductor layer positioned inside the second semiconductor layer, the eighth semiconductor layer being positioned at a boundary between the transistor region and the diode region, the eighth semiconductor layer being of the second conductivity type,
a portion of the second semiconductor layer being positioned between the eighth semiconductor layer and the first semiconductor layer,
an interface between the first semiconductor layer and the second semiconductor layer not including a step above the eighth semiconductor layer.

2. The device according to claim 1, wherein
the eighth semiconductor layer is positioned at the diode region side in the direction crossing the first direction with respect to the boundary between the transistor region and the diode region.

3. The device according to claim 1, wherein
the eighth semiconductor layer contacts the third semiconductor layer.

4. The device according to claim 1, wherein
the eighth semiconductor layer is separated from the third semiconductor layer in the first direction.

5. The device according to claim 1, wherein
the portion of the second semiconductor layer positioned on the eighth semiconductor layer does not protrude into the first semiconductor layer.

6. The device according to claim 1, wherein
a distance in the first direction between the eighth semiconductor layer and the seventh semiconductor layer is less than a distance in the first direction between the sixth semiconductor layer and the seventh semiconductor layer.

7. The device according to claim 6, wherein
the distance in the first direction between the eighth semiconductor layer and the seventh semiconductor layer is less than a distance in the first direction between the third semiconductor layer and the fourth semiconductor layer.

8. The device according to claim 1, wherein
a thickness in the first direction of a portion of the semiconductor part in which the eighth semiconductor layer is positioned is equal to a thickness in the first direction of a portion of the semiconductor part in which the eighth semiconductor layer is not positioned.

9. The device according to claim 1, wherein
a thickness in the first direction of the first semiconductor layer above the eighth semiconductor layer is equal to a thickness in the first direction of the first semiconductor layer which is not positioned above the eighth semiconductor layer.

10. A semiconductor device, comprising:
a first electrode;
a second electrode;
a semiconductor part positioned between the first electrode and the second electrode in a first direction, the semiconductor part including a transistor region and a diode region, the diode region being adjacent to the transistor region in a direction crossing the first direction; and
a third electrode positioned in the semiconductor part in at least the transistor region,
the semiconductor part including
a first semiconductor layer positioned in the transistor region and the diode region, the first semiconductor layer being of a first conductivity type,
a second semiconductor layer positioned between the first electrode and the first semiconductor layer in the transistor region and the diode region, the second semiconductor layer being of the first conductivity type and having a higher first-conductivity-type impurity concentration than the first semiconductor layer,
a third semiconductor layer positioned between the first electrode and the second semiconductor layer in the transistor region, the third semiconductor layer being of a second conductivity type and being electrically connected with the first electrode,
a fourth semiconductor layer positioned between the first semiconductor layer and the second electrode in the transistor region, the fourth semiconductor layer being of the second conductivity type,
a fifth semiconductor layer positioned between the fourth semiconductor layer and the second electrode in the transistor region, the fifth semiconductor layer being of the first conductivity type and being electrically connected with the second electrode,
a sixth semiconductor layer positioned between the first electrode and the second semiconductor layer in the diode region, the sixth semiconductor layer being adjacent to the third semiconductor layer in the direction crossing the first direction, the sixth semiconductor layer being electrically connected with the first electrode, the sixth semiconductor layer being of the first conductivity type and having a higher first-conductivity-type impurity concentration than the first semiconductor layer,
a seventh semiconductor layer positioned between the first semiconductor layer and the second electrode in the diode region, the seventh semiconductor layer being of the second conductivity type and being electrically connected with the second electrode, and
an eighth semiconductor layer positioned inside the second semiconductor layer, the eighth semiconductor layer being positioned between a boundary between the transistor region and the diode region and a boundary between the third semiconductor layer and the sixth semiconductor layer in the direction crossing the first direction, the eighth semiconductor layer being of the second conductivity type,
a portion of the second semiconductor layer being positioned between the eighth semiconductor layer and the first semiconductor layer,
an interface between the first semiconductor layer and the second semiconductor layer not including a step above the eighth semiconductor layer.

11. The device according to claim 10, wherein
the eighth semiconductor layer contacts the third semiconductor layer.

12. The device according to claim 10, wherein
the eighth semiconductor layer is separated from the third semiconductor layer in the first direction.

13. The device according to claim 10, wherein
the portion of the second semiconductor layer positioned on the eighth semiconductor layer does not protrude into the first semiconductor layer.

14. The device according to claim 10, wherein
a distance in the first direction between the eighth semiconductor layer and the seventh semiconductor layer is less than a distance in the first direction between the sixth semiconductor layer and the seventh semiconductor layer.

15. The device according to claim 14, wherein
the distance in the first direction between the eighth semiconductor layer and the seventh semiconductor layer is less than a distance in the first direction between the third semiconductor layer and the fourth semiconductor layer.

16. The device according to claim 10, wherein
a thickness in the first direction of a portion of the semiconductor part in which the eighth semiconductor layer is positioned is equal to a thickness in the first direction of a portion of the semiconductor part in which the eighth semiconductor layer is not positioned.

17. The device according to claim 10, wherein
a thickness in the first direction of the first semiconductor layer above the eighth semiconductor layer is equal to a thickness in the first direction of the first semiconductor layer which is not positioned above the eighth semiconductor layer.
